(19) United States
(12) Patent Application Publication
(10) Pub. No.: US 2024/0301544 A1
(43) Pub. Date: Sep. 12, 2024

(54) ULTRASENSITIVE AND SELECTIVE SENSORS FOR GLUCOSE DETECTION BASED ON THIOL-FUNCTIONALIZED HETEROGENOUS GOLD/GRAPHENE/COPPER FILM

(71) Applicant: KING FAISAL UNIVERSITY, AL-AHSA (SA)

(72) Inventors: CHAWKI AWADA, AL-AHSA (SA); HASSAN HAMMUD, AL-AHSA (SA); FRANCESCO RUFFINO, AL-AHSA (SA)

(21) Appl. No.: 18/637,396

(22) Filed: Apr. 16, 2024

Related U.S. Application Data
(63) Continuation-in-part of application No. 18/120,302, filed on Mar. 10, 2023.

(51) Int. Cl. C23C 14/18; C23C 16/01; C23C 16/26; C23C 16/56; G01N 27/30

(52) U.S. Cl. CPC C23C 14/18; C23C 16/01; C23C 16/26; C23C 16/56; G01N 27/301; G01N 27/308

(57) ABSTRACT

An electro-chemical sensor based on 4-nitrothiophenol (4-NTP) functionalized heterogeneous layers of gold/graphene/Cu for highly sensitive detection of sugars, alcohols, and/or organic compounds in a sample is developed. 4-NTP molecules were immobilized into the surface of gold nanostructures. Due to the adsorption of 4-NTP on the surface, the new sensors showed more sensitivity and selectivity than conventional sensors.

### CROSS-REFERENCE TO RELATED APPLICATIONS

This application is a continuation-in-part of U.S. patent application Ser. No. 18/120,302, filed on Mar. 10, 2023.

### BACKGROUND

### Field

The disclosure of the present patent application relates to an electro-chemical sensor based on 4-nitrothiophenol (4-NTP) functionalized heterogeneous layers of gold/graphene/Cu for highly sensitive detection of alcohols, sugars, and/or organic compounds in a sample.

### Description of Related Art

Electrodes are used in electrochemical sensing applications. The technology of conventional, macro-sized electrodes has been developed over a long period of time. With the advance of miniaturized technologies for portable, micro-sized electrochemical sensors, the electrodes themselves have to be miniaturized as well.

For example, conventional macro-sized reference electrodes in aqueous/wet conditions typically use a silver/silver chloride composite with a potassium chloride solution that helps to stabilize the silver chloride that is coated on the silver wire. Additionally, they must be maintained as wet. This arrangement cannot be used for micro-sized reference electrodes (microelectrodes) due to the small space available in a micro-sized electrochemical sensor, which complicates miniaturization of a separate solution system of potassium chloride that would stabilize the solid state. Therefore, a solid-state electrode is the preferred type of micro-sized electrode. For desired performance, the potential of a reference electrode should be stable or invariant during electrochemical sensing. One problem with current reference solid state electrodes is that their potential is not stable. The instability is because the silver chloride is dissolved during operation.

Conventional macro-sized working electrodes, especially those requiring the use of a membrane such as an ion selective electrode, also pose challenges when miniaturizing, because conventional working electrode membranes also require a separate solution system. Additionally, chemically selective membranes, such as ion selective electrode membranes, deposited on solid state working electrodes are known to present problems of instability. This results in shifts in the measured potential of the working electrode. The instability of the potential is thought to be caused by patches that are formed at the membrane/working electrode interface. The patches cause random collection of water at the interface, which results in the variation of the amount of the analyte that can reach the interface. Solutions that have been reported for this problem include the use of conducting polymers as interlayer films between the electrode and the ion selective membrane. However, these interlayer films create other issues, such as environmental sensitivity, including sensitivity to light or sample changes, such as pH shifts, which create problems when detecting chemical concentrations in samples that have changing compositions, such as in the environment or in biofluids, such as bodily fluids.

Thus, an improved electro-chemical sensor solving the aforementioned problems is desired.

### SUMMARY OF THE INVENTION

The present subject matter relates to an electro-chemical sensor based on 4-nitrothiophenol (4-NTP) functionalized heterogeneous layers of metal or semiconductor nanostructures/graphene/Cu for highly sensitive detection of alcohols, sugars, and/or organic compounds in a sample.

In an embodiment, the present subject matter relates to an electro-chemical sensor comprising a composite film electrode, wherein the composite film electrode comprises:
a copper substrate layer;
a graphene layer on a top surface of the copper substrate layer; and
a gold layer formed from RF sputtering gold nanostructures on a top surface of the graphene layer resulting in a quasi-continuous film of gold with a fill fraction of about 80%, wherein the gold layer is functionalized with 4-nitrothiophenol (4-NTP) molecules, and wherein the composite film electrode is mounted on a silver wire.

In another embodiment, the present subject matter relates to an electro-chemical sensor comprising a composite film electrode, wherein the composite film electrode comprises:
a silver wire layer;
a paraffin insulator wrapped around a first portion of the silver wire layer;
a copper substrate layer wrapped on a second portion of the silver wire layer proximate to the first portion, wherein the copper substrate layer forms a conical shape;
a graphene layer on a top surface of the copper substrate layer; and
a gold layer formed from RF sputtering gold nanostructures on a top surface of the graphene layer resulting in a quasi-continuous film of gold with a fill fraction of about 80%, wherein the gold layer is functionalized with 4-nitrothiophenol (4-NTP) molecules.

In another embodiment, the present subject matter relates to a method of making a composite film electrode, comprising
providing a substrate having a graphene layer on top of a copper layer;
depositing a gold film comprising gold nanostructures on the graphene layer to obtain an initial sensor;
immersing the initial sensor in a solution of absolute ethanol and 4-nitrothiophenol (4-NTP) to obtain an initial composite film electrode; and
drying the initial composite film electrode to obtain the composite film electrode.

In a further embodiment, the present subject matter relates to a method for detecting sugar, alcohol, and/or organic compound levels in a sample, the method comprising:
contacting the sample with the electro-chemical sensor as described herein; and
determining the sugar, alcohol, and/or organic compound levels in the sample.

These and other features of the present subject matter will become readily apparent upon further review of the following specification.

### BRIEF DESCRIPTION OF DRAWINGS

FIG. 1 is a front view of a cone shaped glucose sensor based on a thiol-functionalized gold, graphene, and copper film.

FIG. 2 is a quasi-continuous film of gold with a fill fraction of about 80%.

FIG. 3 is a Nyquist plot having a Gold (Au)/Graphene (Gr)/Copper (Cu) composite film electrode without and with 4-NTP (modified) electrodes for electrochemical oxidation of glucose at different concentrations.

FIGS. 4A and 4B show 50× optical images of Gr and 7/5 nm Au/Gr/Cu, respectively.

FIGS. 4C and 4D are graphs showing Raman spectra of Gr/Cu and 7.5 nm Au/Gr/Cu functionalized with 4-NTP, respectively.

FIG. 5 is a schematic representation of electrochemical oxidation of glucose on a 4-NTP modified Au/Gr/Cu electrode.

FIG. 6 is a graph showing a comparison of electroactivity of a Cu/Gr/Au (7.5 nm)-4-NTP modified electrode before and after 100 cycles in the presence of glucose 34 mM.

FIG. 7 is a graph showing a cyclic voltammogram in 0.5 M NaOH of a nano gold electrode and a 4-NTP modified nano gold electrode.

FIG. 8 is a graph showing a comparison between Au/Gr/Cu with and without 4-NTP for electrochemical oxidation of glucose at different concentrations.

FIG. 9 is a graph showing a calibration curve of Current I (mA) vs. concentration of glucose (mM) using a Cu/Gr/Au (7.5 nm)-4-NTP modified electrode.

Similar reference characters denote corresponding features consistently throughout the attached drawings.

### DETAILED DESCRIPTION

The following definitions are provided for the purpose of understanding the present subject matter and for construing the appended patent claims.

### Definitions

Throughout the application, where compositions are described as having, including, or comprising specific components, or where processes are described as having, including, or comprising specific process steps, it is contemplated that compositions of the present teachings can also consist essentially of, or consist of, the recited components, and that the processes of the present teachings can also consist essentially of, or consist of, the recited process steps.

It is noted that, as used in this specification and the appended claims, the singular forms “a”, “an”, and “the” include plural references unless the context clearly dictates otherwise.

In the application, where an element or component is said to be included in and/or selected from a list of recited elements or components, it should be understood that the element or component can be any one of the recited elements or components, or the element or component can be selected from a group consisting of two or more of the recited elements or components. Further, it should be understood that elements and/or features of a composition or a method described herein can be combined in a variety of ways without departing from the spirit and scope of the present teachings, whether explicit or implicit herein.

The use of the terms “include,” “includes”, “including,” “have,” “has,” or “having” should be generally understood as open-ended and non-limiting unless specifically stated otherwise.

The use of the singular herein includes the plural (and vice versa) unless specifically stated otherwise. In addition, where the use of the term “about” is before a quantitative value, the present teachings also include the specific quantitative value itself, unless specifically stated otherwise. As used herein, the term “about” refers to a ±10% variation from the nominal value unless otherwise indicated or inferred.

The term “optional” or “optionally” means that the subsequently described event or circumstance may or may not occur, and that the description includes instances where said event or circumstance occurs and instances in which it does not.

It will be understood by those skilled in the art with respect to any chemical group containing one or more substituents that such groups are not intended to introduce any substitution or substitution patterns that are sterically impractical and/or physically non-feasible.

Unless defined otherwise, all technical and scientific terms used herein have the same meaning as commonly understood to one of ordinary skill in the art to which the presently described subject matter pertains.

Where a range of values is provided, for example, concentration ranges, percentage ranges, or ratio ranges, it is understood that each intervening value, to the tenth of the unit of the lower limit, unless the context clearly dictates otherwise, between the upper and lower limit of that range and any other stated or intervening value in that stated range, is encompassed within the described subject matter. The upper and lower limits of these smaller ranges may independently be included in the smaller ranges, and such embodiments are also encompassed within the described subject matter, subject to any specifically excluded limit in the stated range. Where the stated range includes one or both of the limits, ranges excluding either or both of those included limits are also included in the described subject matter.

Throughout the application, descriptions of various embodiments use “comprising” language. However, it will be understood by one of skill in the art, that in some specific instances, an embodiment can alternatively be described using the language “consisting essentially of” or “consisting of”.

For purposes of better understanding the present teachings and in no way limiting the scope of the teachings, unless otherwise indicated, all numbers expressing quantities, percentages or proportions, and other numerical values used in the specification and claims, are to be understood as being modified in all instances by the term “about”. Accordingly, unless indicated to the contrary, the numerical parameters set forth in the following specification and attached claims are approximations that may vary depending upon the desired properties sought to be obtained. At the very least, each numerical parameter should at least be construed in light of the number of reported significant digits and by applying ordinary rounding techniques.

### Electro-Chemical Sensors

In one embodiment, the present subject matter relates to an electro-chemical sensor comprising a composite film electrode, wherein the composite film electrode includes a copper substrate layer, a graphene layer on a top surface of the copper substrate layer, and a nanostructure layer on a top surface of the graphene later, wherein the nanostructure layer comprises noble metal nanostructures or semiconductor nanostructures. In an embodiment, the nanostructures are functionalized with thiolate molecules. In an embodiment, the semiconductor nanostructures comprise metal oxide nanostructures. In an embodiment, the electro-chemical sensor comprises a composite film electrode, wherein the composite film electrode comprises:
a copper substrate layer;
a graphene layer on a top surface of the copper substrate layer; and
a gold layer formed from gold nanostructures on a top surface of the graphene later, wherein the gold layer is functionalized with 4-nitrothiophenol (4-NTP) molecules.

The sensors and electrodes described herein can be of any suitable size and shape. For example, the electrode can be a wire, a thin film on a surface, a pattern on a flexible substrate, a material, or ink. The electrode may be part of a printed sensor. The electrode can be any suitable thickness that allows the desired formation steps to occur and also allows fabrication into a desired device. The nanocomposite can be coated on substantially all or a portion of the surface of the electrode. For example, the electrode can be a generally two-dimensional shape, and the nanocomposite can be coated on one side, or a portion of one side of the metal electrode. Coating does not necessarily mean a uniform layer is formed. There may be holes, voids, or other areas where there is no nanocomposite or less nanocomposite or more nanocomposite than in other areas, as long as the nanocomposite coated surface performs in the desired manner and with the desired characteristics, as described herein.

In one embodiment, the 4-NTP is adsorbed onto a top surface of the gold layer. In another embodiment, the 4-NTP molecules are attached to the gold layer through sulfur atoms of the 4-NTP molecules. In other embodiments, the 4-NTP molecules can be immobilized into the surface of the gold nanostructures. Surface enhanced Raman scattering can be performed to ensure the adsorption of the 4-NTP and optical enhancement of the gold nanostructures.

In a further embodiment, the gold layer can have a thickness of about 5-10 nm, about 5 nm, about 5.5 nm, about 6 nm, about 6.5 nm, about 7 nm, about 7.5 nm, about 8 nm, about 8.5 nm, about 9 nm, about 9.5 nm, or about 10 nm. In one specific embodiment, the gold layer can have a thickness of about 7.5 nm.

Similarly, in another embodiment, the composite film electrode can be mounted on a silver wire. In this embodiment, the silver wire can have a thickness of about 0.1-2 mm, about 0.1 mm, about 0.5 mm, about 1 mm, about 1.5 mm, about 2 mm, or any value in between. In one specific embodiment, the silver wire can have a thickness of about 1 mm.

In another further embodiment, about 0.2-0.3 cm², about 0.2 cm², about 0.21 cm² about 0.22 cm², about 0.23 cm², about 0.24 cm², about 0.25 cm², about 0.26 cm², about 0.27 cm², about 0.28 cm², about 0.29 cm², or about 0.3 cm² of the entire composite film electrode can be mounted on the silver wire. In one specific embodiment, about 0.25 cm² of the entire composite film electrode can be mounted on the silver wire.

Likewise, in another embodiment, the copper substrate layer can have a thickness of about 20-30 microns, about 20 microns, about 21 microns, about 22 microns, about 22 microns, about 23 microns, about 24 microns, about 25 microns, about 26 microns, about 27 microns, about 28 microns, about 29 microns, or about 30 microns. In one specific embodiment, the copper substrate layer can have a thickness of about 25 microns.

Similarly, in a further embodiment, the graphene layer can be a single graphene layer that can have a thickness of about 0.3-0.4 nm, about 0.3 nm, about 0.335 nm, about 0.35 nm, about 0.385 nm, about 4 nm, or any value in between. In one specific embodiment, the graphene layer is a single graphene layer that can have a thickness of about 0.335 nm.

The electro-chemical sensors as described herein can be selective for the detection of, e.g., methanol and/or glucose. Regarding the detection of methanol, the present electro-chemical sensors are capable of detecting methanol in a sample having about 0.2-1.7% methanol, or any value in between. Regarding the detection of glucose, the present electro-chemical sensors are capable of detecting glucose in a sample having about 2-34 mM of glucose, or any value in between.

In one embodiment, the initial composite film electrodes can comprise a nanogold (Au)/graphene (Gr)/copper (Cu) film (Au-7.5 nm/Gr/Cu), while modified electrodes as discussed herein can comprise 4-nitrothiophenol/nanogold/graphene/copper film (4-NTP/Au-7.5nm/Gr/Cu). In this embodiment, the film electrode has an overall area of about 0.25 cm² and can be mounted on a silver wire, for example, a 1 mm silver wire, to provide an electrical connection. In use, a three-electrode cell can be used in, for example, a 0.5M NaOH electrolyte solution during measurement.

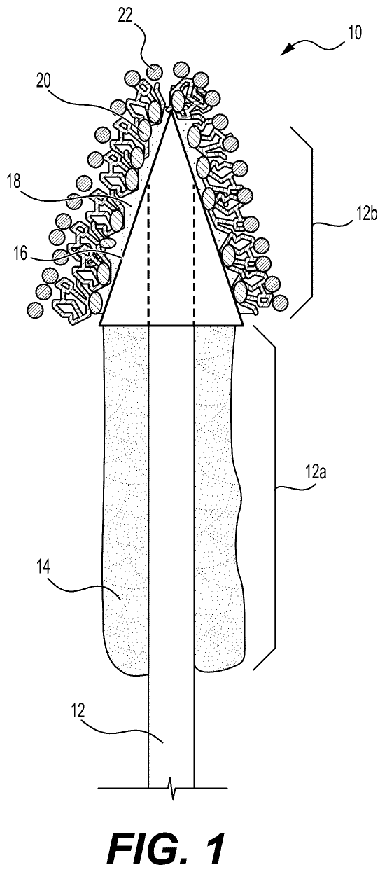

In the non-limiting embodiment of FIG. 1, an electro-chemical sensor 10 is provided including a composite film electrode, the composite film electrode includes a silver wire layer 12, a paraffin insulator 14 wrapped around a first portion 12a of the silver wire layer, a copper substrate layer 16 wrapped on a second portion 12b of the silver wire layer proximate to the first portion. The copper substrate layer 16 forms a conical shape. A graphene layer 18 is formed on a top surface of the copper substrate layer 16. A gold layer 20 is formed on top of the graphene layer 18, wherein the gold layer is functionalized with 4-nitrothiophenol (4-NTP) molecules 22.

The conical shape of copper layer 16 is made by folding a modified copper sheet coated with graphene/gold nanoparticles around the thin cylindrical silver wire layer 12. The conical shape provides electrical contact with the silver wire layer at the wide end of the cone while the smaller pointed end of the cone ensures the prevention of electrolyte solution from entering the inner part of the electrode. The conical shape provides a high surface area for external electrical contact with an electrolyte-glucose solution.

### Methods of Production

In another embodiment, the present subject matter relates to a method of making a composite film electrode, comprising
providing a substrate having a graphene layer on top of a copper layer;
depositing a gold film comprising gold nanostructures on the graphene layer to obtain an initial sensor;
immersing the initial sensor in a solution of absolute ethanol and 4-nitrothiophenol (4-NTP) to obtain an initial composite film electrode; and
drying the initial composite film electrode to obtain the composite film electrode.

In one specific embodiment, the present methods can be used to prepare a gold film comprising gold nanostructures having a thickness of about 7.5 nm on a graphene layer. 4-NTP can then be deposited on this gold film layer.

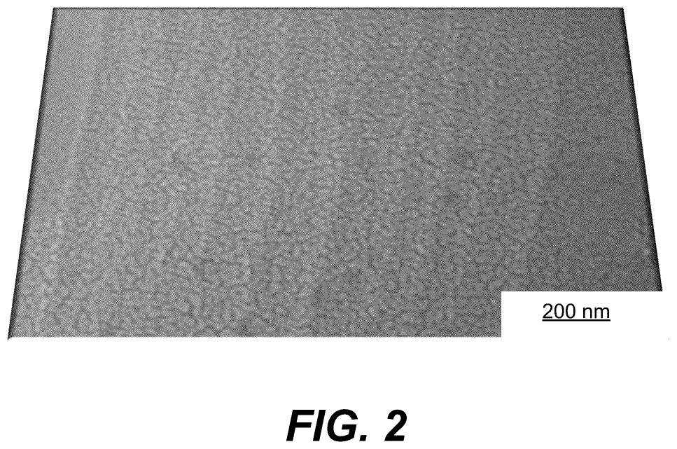

As shown in FIG. 2, the gold layer may be formed by RF sputtering gold nanostructures on a top surface of a graphene layer resulting in a percolative, two-dimensional (2D) quasi-continuous film of gold with a fill fraction of about 80%. The percolative film structure aims to maximize the contact area of the gold sensing material for increased sensitivity and lower detection limits, as well as faster response times. A percolative, quasi-continuous film involves a network of interconnected pathways formed by the presence of particles, in this case gold nanostructures, within the film.

### Methods of Use

In another aspect, the present subject matter relates to a method for detecting sugar, alcohol, and/or organic compound levels in a sample, the method comprising:
contacting the sample with an electro-chemical sensor as described herein; and determining the sugar, alcohol, and/or organic compound levels in the sample.

In this regard, the present electro-chemical sensors can be used to detect a sugar, alcohol, and/or organic compound in a sample comprising a food, a beverage, or a blood sample. In certain non-limiting examples, the alcohol can be methanol or ethanol, and the sensor can be selective for the detection of methanol in a sample having 0.2-1.7% methanol. In this regard, the electrochemical measurement of methanol performed on the gold modified electrodes described herein using, for example, cyclic voltammetry, can exhibit an increase in sensitivity of at least 3 times greater than standard sensors.

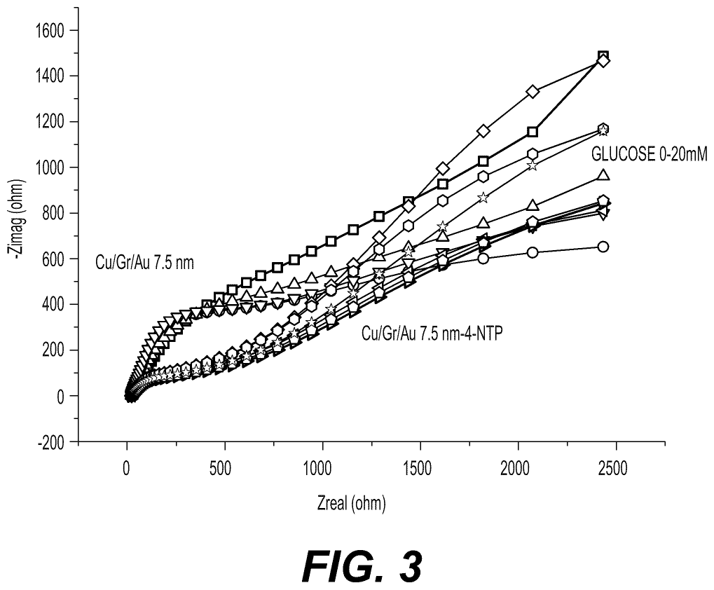

In other non-limiting examples, the sugar can be glucose or fructose, and the sensor can be selective for the detection of glucose in a sample having 2-34 mM of glucose. In this regard, FIG. 3 shows a schematic representation of the electrochemical oxidation of glucose on the present 4-NTP modified Au/Gr/Cu electrode permitting the present glucose measurements to be taken.

In a further non-limiting example, the organic compound can be urea.

The present teachings are illustrated by the following examples.

### EXAMPLE 1

This example provides a method for making the electrodes as described herein. A copper (Cu)/graphene substrate was acquired from the graphene supermarket (https://www.graphene-supermarket.com/collections/cvd-graphene/products/copy-of-single-layer-graphene-on-copper-foil-2x2). This substrate was a standard Copper foil (thickness: 25 micron) on which a single layer graphene was grown by the Chemical Vapor Deposition technique (Science 5 Jun. 2009: Vol. 324. no. 5932, pp. 1312-1314, the entire contents of which are incorporated herein by reference). This graphene layer was grown on copper foil and was continuous across copper surface steps and grain boundaries, see https://www.graphene-supermarket.com/collections/cvd-graphene/products/copy-of-single-layer-graphene-on-copper-foil-2x2). The single layer graphene grown on the Cu surface was of excellent quality (very low amount of defects and disorder) as confirmed by the Raman spectrum from: https://www.graphene-supermarket.com/collections/cvd-graphene/products/copy-of-single-layer-graphene-on-copper-foil-2x2.

Au depositions were carried out onto graphene-graphene slides using a RF Emitech K550X sputter coater apparatus, clamping the substrates against the cathode located straight opposite the target source (99.999% purity target). The electrodes were laid at a distance of 40 mm under Ar flow keeping a pressure of 0.02 mbar in the chamber. During the depositions, the working current and the deposition time were set to obtain an effective thickness for the deposited Au films of 7.5 nm as checked by subsequent ex-situ Rutherford backscattering analyses performed using 2 MeV 4He+ backscattered ions at 165° (with a statistical error of 5%).

After fabricating the sensors, they were immersed in a solution of absolute ethanol with 10⁻³ M of 4-NTP molecules during 24 hours. Then, the sensors were dried with gaseous nitrogen.

### EXAMPLE 2

FIG. 1 shows a Nyquist plot comparing the ability of Au/Gr/Cu electrodes, with and without the 4-NTP modification, to electrochemically oxidate glucose at different concentrations from 2-34 mM. R (Ohm) values for the thiol (4-NTP) modified electrode (2) are smaller than without the thiol modified electrode (1). This demonstrates the 4-NTP modified electrode (2) possessed a faster charge transfer for electrooxidation of glucose than did electrode (1).

Similarly, FIGS. 2A and 2B show 50× optical images of Gr and 7.5 nm Au/Gr/Cu. Likewise, FIGS. 2C and 2D show Raman spectra of Gr/Cu and 7.5 nm Au/Gr/Cu functionalized with 4-NTP. G and 2D bands of Gr are located at 1578 cm⁻¹ and 2633 cm⁻¹, respectively. C—H, C—N, NO2, and C-C are the vibrational modes of 4-NTP located at 1080 cm⁻¹, 1110 cm⁻¹, 1337 cm⁻¹, and 1574 cm⁻¹, respectively. A laser wavelength of 632.8 nm, using irradiated power 500 o microwatts. at 1800 gr/mm, 0.23 cm⁻¹, and 15 s integration, was used for each spectra. Each spectra was averaged over three different positions for both Gr and 4-NTP.

### EXAMPLE 3

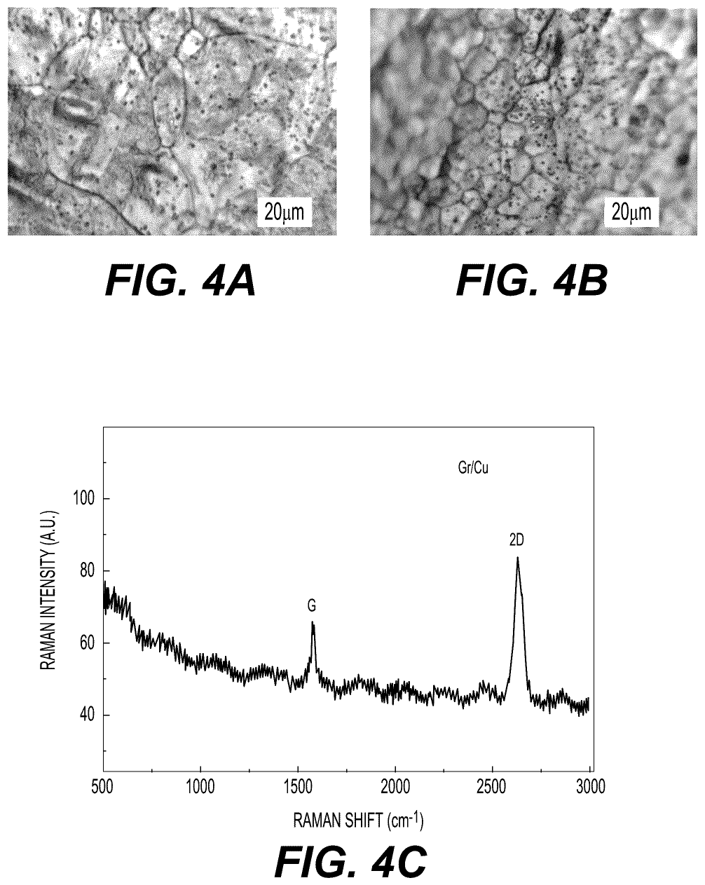

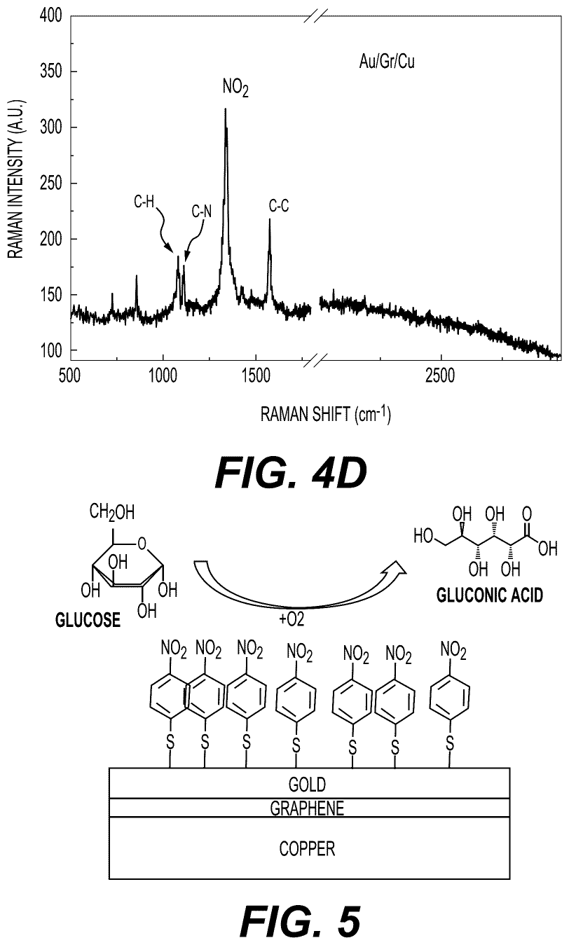

As shown in FIG. 4, the stability of the present electrodes is compared in the presence of glucose at a concentration of 33.82 mM, NaOH 0.5 M, at a scan rate of 50 mV/s, before and after 100 cycle cyclic voltammetry in the scan range −1.0 V to 1.0 V. As can be seen, there is no decrease in the oxidation peaks A1 and A2.

### EXAMPLE 4

FIG. 5 is a cyclic voltammogram providing evidence of attachment of 4-NTP molecules to the gold nanoparticles in the Au layer by comparing the electroactivity of nano gold electrode CA2 (1) and CA2 thiol modified nanogold electrode (2) in 0.5 M NaOH where enhancement in electroactivity is clear for electrode (2) from the increase in currents of oxidation peaks A1, A2 and A3 and also reduction peaks C0, C1, C2 and C3 compared to electrode (1).

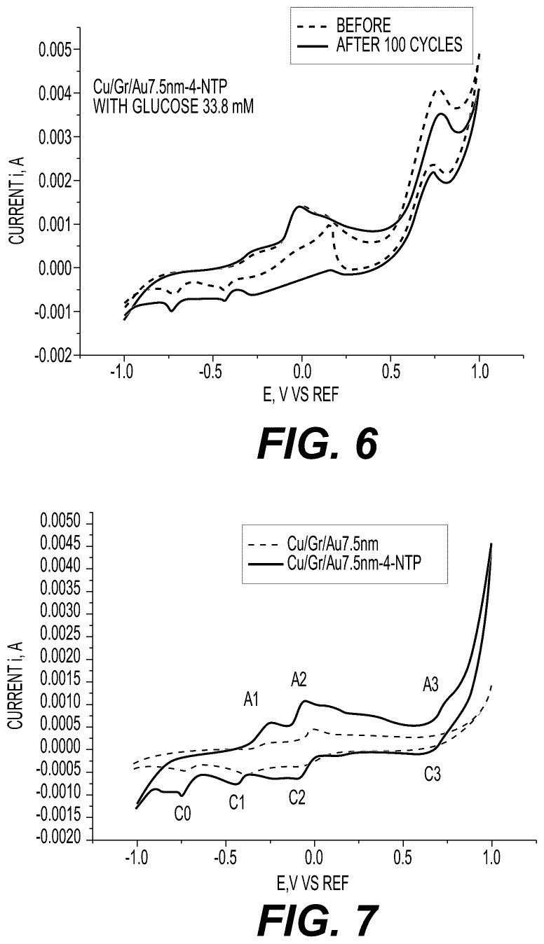

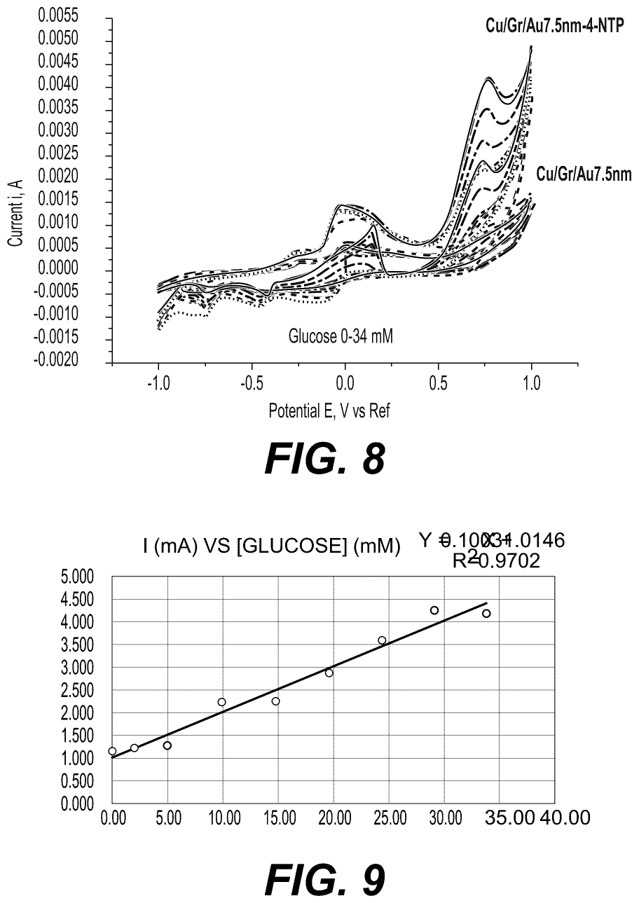

Similarly, FIG. 6 shows a comparison between the current recorded for Au/Gr/Cu sensors with 4-NTP and without 4-NTP. The values shown are for electrochemical oxidation of glucose at different concentrations across 2-34 nM, in the range of −1.0 to +1.0 V. For 34 mM, the ratio is about 3 mA/1 mA=3, demonstrating the sensors modified with 4-NTP have an approximately 3× sensitivity in comparison to those without the 4-NTP modification. Further, these results show the sensitivity of the presently described sensors in microampere/mM*cm2 is 10-100× more than the sensitivity shown in the literature (see Table 1. Performance comparison of the proposed sensor to the previous works, Haghparas et al., https://doi.org/10.1038/s41598-020-79460-2, the contents of which are hereby incorporated by reference in their entirety.)

Based on the cyclic voltammetry study, the sensitivity obtained was 0.0449 mA/mM and 0.1003 mA/mM or (179.6 μA/mM·cm2 and 401.2 μA/mM·cm2) for graphene nanogold electrode 1 and graphene nanogold thiol electrode 2, respectively. The lower detection limit of 0.5 mM was the same for both electrodes.

FIG. 7 shows a representative calibration curve for the determination of glucose using the graphene nanogold thiol electrode 2. As shown in FIG. 7, Current I (mA) versus concentration of glucose (mM) was obtained from the oxidation peak A3 using the CA2 CuGr thiol Au (7.5 nm) modified electrode (2) in 0.5M NaOH.

It is to be understood that the electro-chemical sensors are not limited to the specific embodiments described above, but encompass any and all embodiments within the scope of the generic language of the following claims enabled by the embodiments described hercin, or otherwise shown in the drawings or described above in terms sufficient to enable one of ordinary skill in the art to make and use the claimed subject matter.

1. An electro-chemical sensor comprising a composite film electrode, wherein the composite film electrode comprises:
a copper substrate layer;
a graphene layer on a top surface of the copper substrate layer; and
a gold layer formed from RF sputtering gold nanostructures on a top surface of the graphene layer resulting in a two-dimensional quasi-continuous film of gold with a fill fraction of about 80%, wherein the gold layer is functionalized with 4-nitrothiophenol (4-NTP) molecules, and wherein the composite film electrode is mounted on a silver wire.

2. The electro-chemical sensor of claim 1, wherein the 4-NTP molecules are adsorbed onto a top surface of the gold layer.

3. The electro-chemical sensor of claim 1, wherein the electro-chemical sensor is selective for the detection of glucose in a sample having 2-34 mM of glucose.

4. The electro-chemical sensor of claim 1, wherein the gold layer has a thickness of about 7.5 nm.

5. The electro-chemical sensor of claim 1, wherein the silver wire has a thickness of about 1 mm.

6. The electro-chemical sensor of claim 5, wherein about 0.25 cm² of the composite film electrode is mounted on the silver wire.

7. The electro-chemical sensor of claim 2, wherein the 4-NTP molecules are attached to the gold layer through sulfur atoms of the 4-NTP molecules.

8. The electro-chemical sensor of claim 1, wherein the copper substrate layer has a thickness of about 25 microns.

9. The electro-chemical sensor of claim 1, wherein the graphene layer is a single graphene layer having a thickness of about 0.335 nm.

10. An electro-chemical sensor comprising a composite film electrode, wherein the composite film electrode comprises:
a silver wire layer;
a paraffin insulator wrapped around a first portion of the silver wire layer;
a copper substrate layer wrapped on a second portion of the silver wire layer proximate to the first portion, wherein the copper substrate layer forms a conical shape;
a graphene layer on a top surface of the copper substrate layer; and
a gold layer formed from RF sputtering gold nanostructures on a top surface of the graphene layer resulting in a quasi-continuous film of gold with a fill fraction of about 80%,
wherein the gold layer is functionalized with 4-nitrothiophenol (4-NTP) molecules.
